(19) United States
(12) Patent Application Publication
(10) Pub. No.: US 2023/0016416 A1
(43) Pub. Date: Jan. 19, 2023

(54) MEMS MODULE AND METHOD OF MANUFACTURING MEMS MODULE

(71) Applicant: ROHM CO., LTD., Kyoto (JP)

(72) Inventors: Toru HIGUCHI, Kyoto (JP); Kosuke YAMASHIRO, Kyoto (JP)

(73) Assignee: ROHM CO., LTD., Kyoto (JP)

(21) Appl. No.: 17/861,834

(22) Filed: Jul. 11, 2022

(30) Foreign Application Priority Data
Jul. 13, 2021 (JP) 2021-115773

(51) Int. Cl. B81B 3/00; H01L 29/84; B81B 7/02; G01L 9/00; B81C 1/00; B81B 7/00

(52) U.S. Cl. CPC B81B 3/0021; H01L 29/84; B81B 7/02; G01L 9/0042; B81C 1/00166; B81C 1/00158; B81C 1/00523; B81C 1/00357; B81B 7/0019; B81B 2201/0264; B81B 2203/0315; B81B 2203/0323; B81B 2203/04; B81C 2201/013; B81C 2203/033

(57) ABSTRACT

A MEMS module includes: a MEMS element provided with a substrate in which a hollow portion is formed, and including a movable portion, which is a part of the substrate, around the hollow portion, the movable portion having a thickness whose shape is changeable by an air pressure difference between an air pressure inside the hollow portion and an air pressure outside the substrate; and an electronic component, to which an output signal of the MEMS element is inputted, formed on the substrate, wherein the electronic component and the MEMS element are spaced apart from each other in a direction perpendicular to a thickness direction of the movable portion.

### CROSS-REFERENCE TO RELATED APPLICATION

This application is based upon and claims the benefit of priority from Japanese Patent Application No. 2021-115773, filed on Jul. 13, 2021, the entire contents of which are incorporated herein by reference.

### TECHNICAL FIELD

The present disclosure relates to a MEMS module, and a method of manufacturing a MEMS module.

### BACKGROUND

There is known a MEMS (Micro Electromechanical System) element, which is a device having a machine element component and an electronic circuit integrated by utilizing a micromachining technique used for manufacturing a semiconductor integrated circuit.

The MEMS element has a hollow portion and a movable portion that closes the hollow portion. In the configuration of the related art, the hollow portion is formed by bonding a glass substrate to the back side of a Si substrate in which a recess is formed. In this bonding, it is required to prevent formation of a fine gap when the hollow portion is sealed. Further, when finishing the movable portion as a relatively thin part, it is necessary to dig the Si substrate deeply in order to form a recess.

In addition, the MEMS element may be used by being incorporated into a pressure sensor. In the pressure sensor, a change in outside air pressure changes the stress generated at the end of the movable portion of the MEMS element, the gauge resistance is changed according to the deformation of the movable portion, and the change in the gauge resistance is outputted as a change in output voltage.

However, in the pressure sensor, the gauge resistance is changed not only by the change in the external air pressure but also by the external stress transmitted to the movable portion (also referred to as a membrane) of the MEMS element. Since the above output voltage is changed by the factors other than the change in the outside air pressure, it may be difficult to accurately detect the change in the outside air pressure. One aspect of the present embodiment provides a MEMS module capable of accurately deriving a change in outside air pressure. Another aspect of the present embodiment provides a method of manufacturing a MEMS module.

### SUMMARY

In the present embodiments, it is possible to suppress stress caused by factors other than a change in an external air pressure applied to a MEMS element by providing the MEMS element and the electronic component, to which the output signal of the MEMS element is inputted and which are included in the MEMS module, on the same substrate. One aspect of the embodiments is as follows.

According to one embodiment of the present disclosure, there is provided a MEMS module including: a MEMS element provided with a substrate in which a hollow portion is formed, and including a movable portion, which is a part of the substrate, around the hollow portion, the movable portion having a thickness whose shape is changeable by an air pressure difference between an air pressure inside the hollow portion and an air pressure outside the substrate; and an electronic component, to which an output signal of the MEMS element is inputted, formed on the substrate, wherein the electronic component and the MEMS element are spaced apart from each other in a direction perpendicular to a thickness direction of the movable portion.

According to another embodiment of the present disclosure, there is provided a method of manufacturing a MEMS module, including: forming a plurality of grooves in a semiconductor layer included in a substrate; forming a MEMS element including a hollow portion formed by: etching the semiconductor layer in a direction perpendicular to a depth direction of the grooves from bottom surfaces of the grooves to connect the grooves; performing a heat treatment on the semiconductor layer; and filling the grooves with a part of the semiconductor layer melted by the heat treatment; and forming an electronic component, to which an output signal of the MEMS element is inputted, on the substrate, wherein the electronic component and the MEMS element are spaced apart from each other in the direction perpendicular to the depth direction of the grooves.

According to yet another embodiment of the present disclosure, there is provided a method of manufacturing a MEMS module, including: preparing a first substrate provided with a semiconductor layer and a second substrate in which a semiconductor layer is stacked on an oxide film; forming an opening in the first substrate; forming a MEMS element including a hollow portion formed in the opening of the first substrate by bonding the second substrate on the first substrate in which the opening is formed; and forming an electronic component, to which an output signal of the MEMS element is inputted, on the first substrate, wherein the electronic component and the MEMS element are spaced apart from each other in a direction perpendicular to a depth direction of the opening.

### BRIEF DESCRIPTION OF DRAWINGS

The accompanying drawings, which are incorporated in and constitute a part of the specification, illustrate embodiments of the present disclosure.

FIG. 1 is a perspective view showing a MEMS module according to a first embodiment.

FIG. 2 is a perspective view of a main part showing the MEMS module according to the first embodiment.

FIG. 3 is a cross-sectional view taken along line III-III in FIG. 1.

FIG. 4 is a plan view showing an example of a MEMS element and an electronic component according to the first embodiment.

FIG. 5 is a cross-sectional view taken along line V-V in FIG. 4.

FIG. 6 is a cross-sectional view (first cross-sectional view) showing a manufacturing method of an example of the MEMS element and the electronic component according to the first embodiment.

FIG. 7 is a cross-sectional view (second cross-sectional view) showing a manufacturing method of an example of the MEMS element and the electronic component according to the first embodiment.

FIG. 8 is a cross-sectional view (third cross-sectional view) showing a manufacturing method of an example of the MEMS element and the electronic component according to the first embodiment.

FIG. 9 is a cross-sectional view (fourth cross-sectional view) showing a manufacturing method of an example of the MEMS element and the electronic component according to the first embodiment.

FIG. 10 is a cross-sectional view (fifth cross-sectional view) showing a manufacturing method of an example of the MEMS element and the electronic component according to the first embodiment.

FIG. 11 is a cross-sectional view (sixth cross-sectional view) showing a manufacturing method of an example of the MEMS element and the electronic component according to the first embodiment.

FIG. 12 is a cross-sectional view showing a MEMS module according to a second embodiment.

FIG. 13 is a cross-sectional view (first cross-sectional view) showing a manufacturing method of an example of the MEMS element and the electronic component according to the second embodiment.

FIG. 14 is a cross-sectional view (second cross-sectional view) showing a manufacturing method of an example of the MEMS element and the electronic component according to the second embodiment.

FIG. 15 is a cross-sectional view (third cross-sectional view) showing a manufacturing method of an example of the MEMS element and the electronic component according to the second embodiment.

FIG. 16 is a cross-sectional view (fourth cross-sectional view) showing a manufacturing method of an example of the MEMS element and the electronic component according to the second embodiment.

FIG. 17 is a cross-sectional view (fifth cross-sectional view) showing a manufacturing method of an example of the MEMS element and the electronic component according to the second embodiment.

FIG. 18 is a plan view showing a MEMS module according to a third embodiment.

FIG. 19 is a cross-sectional view taken along line V-V in FIG. 18.

FIG. 20 is a cross-sectional view showing a MEMS module according to a fourth embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Next, the present embodiments will be described with reference to the drawings. In the description of the drawings described below, the same or similar parts are designated by the same or similar reference numerals. However, it should be noted that the drawings are schematic and the relationship between the thickness and the plane dimension of each component is different from the actual one. Therefore, the specific thickness and dimension should be determined in consideration of the following description. In addition, it goes without saying that parts having different dimensional relationships and ratios are included in the drawings.

Further, the embodiments described below exemplify devices and methods for embodying the technical idea, and do not specify the material, shape, structure, arrangement, etc. of each component. The present embodiments may be modified in various ways within the scope of the claims.

One specific aspect of the present embodiments is as follows.

<1> A MEMS module including: a MEMS element provided with a substrate in which a hollow portion is formed, and including a movable portion, which is a part of the substrate, around the hollow portion, the movable portion having a thickness whose shape is changeable by an air pressure difference between an air pressure inside the hollow portion and an air pressure outside the substrate; and an electronic component, to which an output signal of the MEMS element is inputted, formed on the substrate, wherein the electronic component and the MEMS element are spaced apart from each other in a direction perpendicular to a thickness direction of the movable portion.

<2> The MEMS module of <1>, wherein the substrate includes a groove, which extends from a main surface of the substrate in a thickness direction of the substrate, between the MEMS element and the electronic component.

<3> The MEMS module of <2>, further including: a first wiring having a region located on an outer edge side of the substrate from an end of the groove, in a direction in which the electronic component and the MEMS element are spaced apart from each other and a direction which is perpendicular to the thickness direction of the movable portion, wherein the MEMS element and the electronic component are electrically connected to the first wiring.

<4> The MEMS module of any one of <1> to <3>, further including: a protective film including an opening on the substrate, wherein the protective film covers at least a part of the electronic component, and wherein the opening is located above the movable portion when viewed in the thickness direction of the movable portion.

<5> The MEMS module of any one of <1> to <4>, further including: a printed circuit board; and a stress relaxation material arranged between the printed circuit board and the MEMS element, wherein a thickness of the stress relaxation material is 35 to 80 μm.

<6> The MEMS module of <5>, further including: a second wiring configured to electrically connect the printed circuit board and the electronic component, wherein the second wiring is electrically connected to the electronic component, on a side of the electronic component that is opposite to a side on which the MEMS element is located.

<7> The MEMS module of any one of <1> to <6>, wherein the substrate is made of silicon.

<8> A method of manufacturing a MEMS module, including: forming a plurality of grooves in a semiconductor layer included in a substrate; forming a MEMS element including a hollow portion formed by: etching the semiconductor layer in a direction perpendicular to a depth direction of the grooves from bottom surfaces of the grooves to connect the grooves; performing a heat treatment on the semiconductor layer; and filling the grooves with a part of the semiconductor layer melted by the heat treatment; and forming an electronic component, to which an output signal of the MEMS element is inputted, on the substrate, wherein the electronic component and the MEMS element are spaced apart from each other in the direction perpendicular to the depth direction of the grooves.

<9> The method of <8>, wherein the hollow portion is formed by deep etching and isotropic etching.

<10> The method of <8> or <9>, wherein the heat treatment is performed at 1,100 to 1,200 degrees C. to cause a thermal migration phenomenon in the semiconductor layer to fill the grooves to form the hollow portion.

<11> A method of manufacturing a MEMS module, including: preparing a first substrate provided with a semiconductor layer and a second substrate in which a semiconductor layer is stacked on an oxide film; forming an opening in the first substrate; forming a MEMS element including a hollow portion formed in the opening of the first substrate by bonding the second substrate on the first substrate in which the opening is formed; and forming an electronic component, to which an output signal of the MEMS element is inputted, on the first substrate, wherein the electronic component and the MEMS element are spaced apart from each other in a direction perpendicular to a depth direction of the opening.

<12> The method of <11>, wherein the oxide film is a silicon oxide layer.

<13> The method of any one of <8> to <12>, wherein the semiconductor layer is a silicon layer.

### First Embodiment

A MEMS module A1 according to a first embodiment will be described.

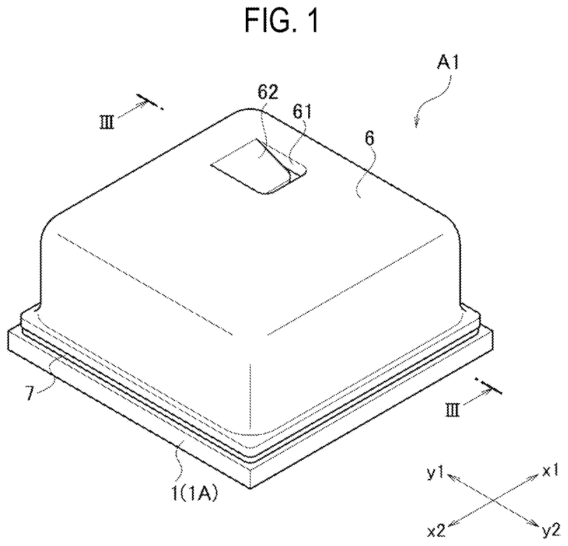

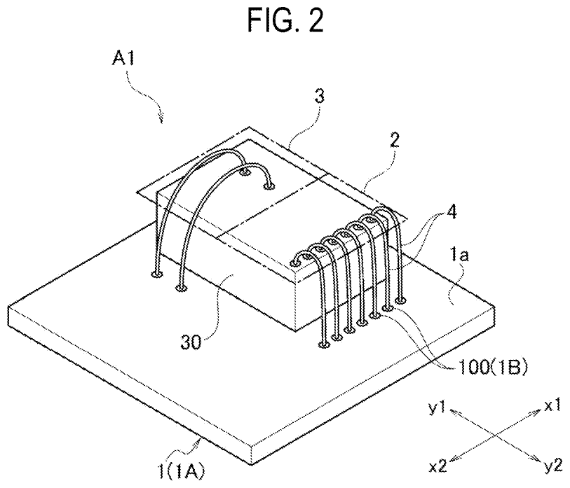

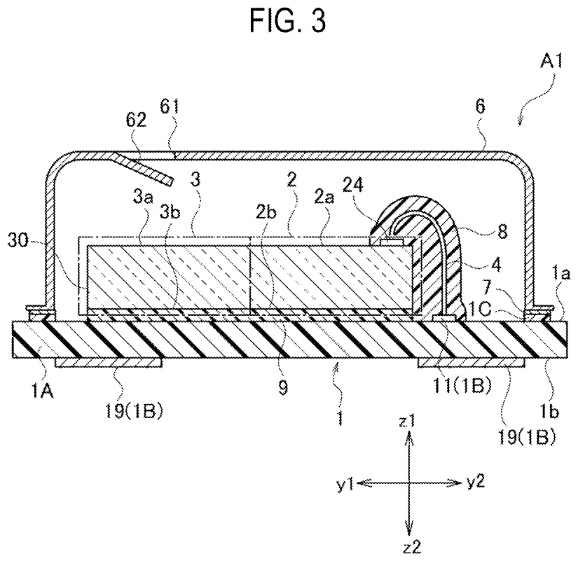

FIG. 1 is a perspective view showing a MEMS module A1. FIG. 2 is a perspective view of a main part of the MEMS module A1 shown in FIG. 1 in which some configurations (a cover 6 and a bonding material 7 to be described later) are not shown. FIG. 3 is a cross-sectional view taken along line III-III in FIG. 1. The MEMS module A1 includes a substrate 1, an electronic component 2, a MEMS element 3, a plurality of wirings 4, a cover 6, and a bonding material 7. The electronic component 2 and the MEMS element 3 are formed on one chip (in the present embodiment, the substrate 30). The MEMS module A1 of the present embodiment is configured to detect an air pressure, and is surface-mounted on, for example, a circuit board of various electronic devices such as a mobile terminal and the like. For example, in a mobile terminal, the MEMS module A1 detects the atmospheric pressure. The detected atmospheric pressure is used as information for calculating an altitude.

Further, in the present embodiment, the thickness direction (plan-view direction) of the MEMS module A1 is defined as a z direction (z1-z2 direction), the direction extending along one side of the MEMS module A1 orthogonal to the z direction is defined as an x direction (x1-x2 direction), and the direction orthogonal to the z direction and the x direction is defined as a y direction (y1-y2 direction). In the present embodiment, the MEMS module A1 has, for example, an x-direction dimension of about 2 mm, a y-direction dimension of about 2 mm, and a z-direction dimension of about 0.8 mm to 1 mm.

As shown in FIG. 2, the substrate 1 is a member for mounting the electronic component 2 and the MEMS element 3 and installing the MEMS module A1 to a circuit board of various electronic devices. As shown in FIG. 3, the substrate 1 includes a base material 1A, a wiring portion 1B, and an insulating layer 1C. The specific configuration of the substrate 1 is not particularly limited as long as it can appropriately support the electronic component 2, the MEMS element 3, and the like. Examples of the substrate 1 include a printed circuit board.

The base material 1A is made of an insulator and is a main constituent member of the substrate 1. Examples of the base material 1A include a glass epoxy resin, a polyimide resin, a phenol resin, ceramics, and the like. The base material 1A has, for example, a rectangular plate shape in a plan view, and includes a mounting surface 1a and an installation surface 1b. The mounting surface 1a and the installation surface 1b face opposite sides in the thickness direction (z direction) of the substrate 1. The mounting surface 1a is a surface facing the z1 direction, and is a surface on which the electronic component 2 and the MEMS element 3 are mounted. The installation surface 1b is a surface facing the z2 direction, and is a surface used when installing the MEMS module A1 to a circuit board of various electronic devices. In the present embodiment, the dimension of the substrate 1 in the z direction is about 100 to 200 μm, and each of the dimensions in the x direction and the y direction is about 2 mm.

The wiring portion 1B forms an electric connection path for electrically connecting the electronic component 2 and the MEMS element 3 to a circuit or the like outside the MEMS module A1. For example, the wiring portion 1B is made of one or more kinds of metals such as Cu, Ni, Ti, and Au, and is formed by plating. In the present embodiment, the wiring portion 1B includes a plurality of mounting surface portions 100 and a back surface pad 19. However, these are examples of a specific configuration of the wiring portion 1B, and the configuration of the wiring portion 1B is not particularly limited.

The mounting surface portions 100 are formed on the mounting surface 1a of the base material 1A, and are a plurality of independent regions spaced apart from each other. Each of the mounting surface portions 100 includes an electrode pad 11, and the end portion of a wiring 4 is bonded to the electrode pad 11.

The back surface pad 19 is provided on the installation surface 1b, and is used as an electrode to be electrically connected and bonded when the MEMS module A1 is installed to a circuit board or the like. The back surface pad 19 is electrically connected to suitable positions of the mounting surface portions 100.

The insulating layer 1C covers an appropriate region of the wiring portion 1B to insulate and protect the region. The insulating layer 1C is made of an insulating material and is formed of, for example, a resist resin. The insulating layer 1C may be formed, for example, in a rectangular annular shape in a plan view.

The bonding material 7 is used for boding the substrate 1 and the cover 6, and is made of, for example, a paste bonding material containing a metal such as Ag or the like. In the present embodiment, the bonding material 7 is provided in a rectangular annular shape in a plan view, and a part of the bonding material 7 is formed in a region overlapping with the insulating layer 1C.

The electronic component 2 is configured to process an electric signal detected by a sensor, and is configured as a so-called ASIC (Application Specific Integrated Circuit) element. The electronic component 2 may include, for example, a temperature sensor, and processes the electric signal detected by the temperature sensor and the electric signal detected by the MEMS element 3. The electronic component 2 multiplexes the electric signal detected by the temperature sensor and the electric signal detected by the MEMS element 3 by using a multiplexer, and converts the electric signals into digital signals by using an analog/digital conversion circuit. Then, a signal processing part performs processing such as amplification, filtering, logical operation, and the like based on a clock signal while using the storage area of a memory part. The processed signals are outputted via the interface. As a result, the MEMS module A1 can appropriately process and then output the signals obtained by detecting the air pressure and the air temperature.

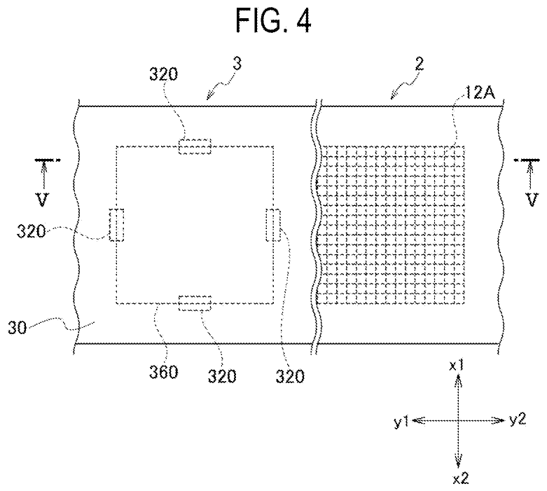

The electronic component 2 is used for control in which various elements are mounted and packaged on the substrate. As shown in FIGS. 3 to 5, the electronic component 2 has a rectangular plate shape in a plan view, and includes a substrate 30 including a main surface 2a and an installation surface 2b. The main surface 2a and the installation surface 2b face opposite sides in the thickness direction (z direction) of the substrate 30. In the present embodiment, the z-direction dimension of the electronic component 2 is the same as that of the MEMS element 3, and is, for example, about 200 to 300 μm. The x-direction dimension of the electronic component 2 is the same as that of the MEMS element 3, and is, for example, about 1 to 1.2 mm. The y-direction dimension of the electronic component 2 is, for example, about 1 to 1.2 mm.

The electronic component 2 is mounted on the mounting surface 1a of the substrate 1 at a position closer to the x1 direction. The electronic component 2 and the substrate 1 are bonded by a stress relaxation material 9 such as a silicone resin, a die attachment film, or the like. A plurality of electrode pads 24 is provided on the main surface 2a of the electronic component 2. The electrode pads 24 are used as electrodes electrically connected to the electrode pads 11 of the substrate 1. Wirings 4 are bonded to the electrode pads 24. The electrode pads 24 are made of a metal such as, for example, Al or an aluminum alloy, and are formed by, for example, sputtering or plating. In the present embodiment, Al layers formed by sputtering are used as the electrode pads 24. The electrode pads 24 are connected to the wiring pattern of the main surface 2a. In the subject specification and the like, the expression “electrically connected” includes a case of being connected via “an object having some kind of electrical action.” In this regard, the “object thing having some kind of electrical action” is not particularly limited as long as it can provide and receive electric signals to and from a connection target. For example, the “object having some kind of electrical action” include an electrode, a wiring, a switching element, a resistance element, an inductor, a capacitive element, and other elements having various functions.

The electrode pads 24 are provided on the main surface 2a of the electronic component 2 on the side opposite to the side where the MEMS element 3 is located (on the y2 direction side of the electronic component 2), and the wirings 4 are bonded to the electrode pads 24. The wirings 4 are protected by a resin 8. By providing the wirings 4 protected by the resin 8 on the main surface 2a on the y2 direction side of the main surface 2a of the electronic component 2, the bonding portions of the wirings 4 can be kept away from the movable portion 340 of the MEMS element 3. Therefore, the influence of the stress caused by the resin 8 on the movable portion 340 can be suppressed.

The MEMS element 3 is configured as an air pressure sensor for detecting an air pressure. The MEMS element 3 detects an air pressure and outputs the detection result as an electric signal to the electronic component 2. As shown in FIGS. 3 to 5, the MEMS element 3 includes a substrate 30 including a main surface 3a and an installation surface 3b. The main surface 3a and the installation surface 3b face opposite sides in the thickness direction (z direction) of the substrate 30. The main surface 3a is a surface facing the z1 direction. The installation surface 3b is a surface facing the z2 direction, and is a surface used when the MEMS element 3 is installed to the substrate 1. In the present embodiment, the dimension of the MEMS element 3 in the z direction is the same as that of the electronic component 2, and is, for example, about 200 to 300 μm. The dimension of the MEMS element 3 in the x direction is the same as that of the electronic component 2, and is, for example, about 1 to 1.2 mm. The dimension of the MEMS element 3 in the y direction is, for example, about 1 to 1.2 mm.

The MEMS element 3 and the substrate 1 are bonded by a stress relaxation material 9 such as a silicone resin, a die attachment film, or the like. Further, the electronic component 2 and the MEMS element 3 are spaced apart from each other in the y direction.

Since the electronic component 2 and the MEMS element 3 are formed on one chip (the substrate 30), the stress relaxation material 9 can be made sufficiently thick to suppress the influence of an external stress on the movable portion 340. For example, if the thickness (dimension in the z direction) of the stress relaxation material 9 is 35 μm or more, the influence of an external stress on the movable portion 340 can be suppressed. Further, as the thickness of the stress relaxation material 9 increases, the external stress decreases. If the thickness of the stress relaxation material 9 exceeds 80 μm, the external stress becomes infinitely small. Therefore, the thickness (dimension in the z direction) of the stress relaxation material 9 is preferably, for example, 35 to 80 μm, and more preferably 45 to 70 μm.

The substrate 30 includes a semiconductor layer. Examples of the semiconductor layer include a silicon layer, and the like. The substrate 30 may be formed of, for example, only a silicon layer, or may be formed of an oxide film such as a silicon oxide layer or the like and a film obtained by stacking silicon layers.

A hollow portion 360 of the MEMS element 3 is provided inside the substrate 30. Further, a part of the substrate 30 around the hollow portion 360 serves as a movable portion 340 of the MEMS element 3. In addition, the substrate 30 is provided with a fixed portion 370 for the MEMS element 3.

The movable portion 340 overlaps with the hollow portion 360 in the z direction, and can move in the z direction in order to detect an air pressure. In the present embodiment, the movable portion 340 has a rectangular shape when viewed in the z direction. The film thickness T of the movable portion 340 may be a thickness of, for example, 5 to 15 μm, whose shape is changeable by the pressure difference between the air pressure inside the hollow portion 360 and the air pressure outside the substrate 30.

The hollow portion 360 is a cavity provided inside the substrate 30, and is sealed in the present embodiment. The hollow portion 360 may be kept in vacuum. Further, in the present embodiment, the hollow portion 360 has a rectangular shape when viewed in a z direction. However, the present disclosure is not limited thereto. The depth (dimension in the z direction) of the hollow portion 360 is, for example, 5 to 15 μm.

The fixed portion 370 is a portion that supports the movable portion 340, and is a portion that is fixed to the substrate 1 when the movable portion 340 operates. In the present embodiment, the portion of the substrate 30 other than the movable portion 340 and the hollow portion 360 is referred to as a fixed portion 370.

In the present embodiment, the movable portion 340 and the fixed portion 370 are formed of one and the same semiconductor having no bonding portion at the boundary between the movable portion 340 and the fixed portion 370. The movable portion 340 and the fixed portion 370 are made of, for example, silicon. The movable portion 340 includes a recess in a region 330. The recess is located in a region of the movable portion 340 that overlaps with the hollow portion 360 when viewed in the z direction, and is gently recessed in the z direction.

As will be described later in explaining the manufacturing method, the recess is formed as a part of the substrate melted by the heat treatment fills the grooves. Since the film thickness T of the movable portion 340 is thin only by filling the grooves, an interlayer film 350 may be provided on the movable portion 340 to increase the film thickness T. In the present embodiment, when the interlayer film 350 is provided, the interlayer film 350 includes a region 335 that functions as a part of the movable portion 340. Therefore, the movable portion 340 includes the region 330 of the substrate 30 and the region 335 of the interlayer film 350. Further, the main surface 3a of the MEMS element 3 is a surface of the interlayer film 350 in the z1 direction. In the subject specification and the like, the “flat surface” includes a surface having an average surface roughness of 0.5 μm or less. The average surface roughness can be obtained, for example, in accordance with JIS B 0601: 2013 or ISO 25178. The interlayer film 350 may be made of, for example, the same material as the substrate 30, and may be made of silicon. The provision of the interlayer film 350 is preferable because the surface on which the protective film 10 is formed is a flat surface and the coverage of the protective film 10 is improved.

The MEMS element 3 generates an electric signal according to the shape (distortion degree) of the movable portion 340 changed by the difference between the air pressure inside the hollow portion 360 and the air pressure outside the substrate 30, and outputs the electric signal to the electronic component 2. A gauge resistor 320 whose resistance value changes according to the change in the shape of the movable portion 340 is provided on the main surface 3a of the MEMS element 3.

The electronic component 2 includes a plurality of wirings 12A and a plurality of electrode layers 12B. The electric signal generated by the MEMS element 3 is outputted to the electronic component 2 via the plurality of wirings 12A and the plurality of electrode layers 12B. Some of the wirings 12A are electrically connected to the electrode pads 24 of the electronic component 2, and the electrode pads 24 are electrically connected to the electrode pads 11 of the substrate 1 via the wirings 4.

Further, at least a part of the electronic component 2 and the MEMS element 3 may be covered with the protective film 10. The inside of the electronic component 2 and the MEMS element 3 can be protected by covering them with the protective film 10. Examples of the protective film 10 include a resin, an insulating film, and the like.

The wirings 4 that electrically connect the electrode pads 11 of the substrate 1 to the electrode pads 24 of the electronic component 2 are made of a metal such as, for example, Au or the like. The material of the wirings 4 is not limited, and may be, for example, Al, Cu, or the like. The wirings 4 are bonded to the electrode pad 11 and the electrode pad 24.

The cover 6 is a box-shaped member of a metal material, and is bonded to the mounting surface 1a of the substrate 1 by the bonding material 7 so as to surround the electronic component 2, the MEMS element 3, and the wirings 4. In the illustrated example, the cover 6 has a rectangular shape in a plan view. The cover 6 may be made of a material other than metal. Further, the manufacturing method of the cover 6 is not particularly limited. The space between the cover 6 and the substrate 1 is hollow or filled with a soft resin such as a silicone resin or the like.

As shown in FIGS. 1 and 3, the cover 6 includes an opening 61 and an extension portion 62. The opening 61 is used for introducing the outside air therein. Since the opening 61 is provided and is kept hollow or filled with a soft resin, the MEMS element 3 can detect the air pressure (e.g., the atmospheric pressure) around the MEMS module A1, and the temperature sensor of the electronic component 2 can detect the air temperature around the MEMS module A1. In the present embodiment, only one opening 61 is arranged at a position on the z1 direction side of the MEMS element 3. The number of openings 61 is not particularly limited. The extension portion 62 extends from the edge of the opening 61 and overlaps with at least a part of the opening 61 in a plan view. The extension portion 62 is inclined so as to be located in the z2 direction and come closer to the substrate 1 as it extends away from the edge of the opening 61. Further, in the illustrated configuration, the tip of the extension portion 62 is provided at a position where it avoids the electronic component 2 and the MEMS element 3 in a plan view. In addition, the root of the extension portion 62 is provided at a position where it overlaps with the electronic component 2 and the MEMS element 3. The extension portion 62 may not be provided.

Next, a method of manufacturing the MEMS module A1 will be described.

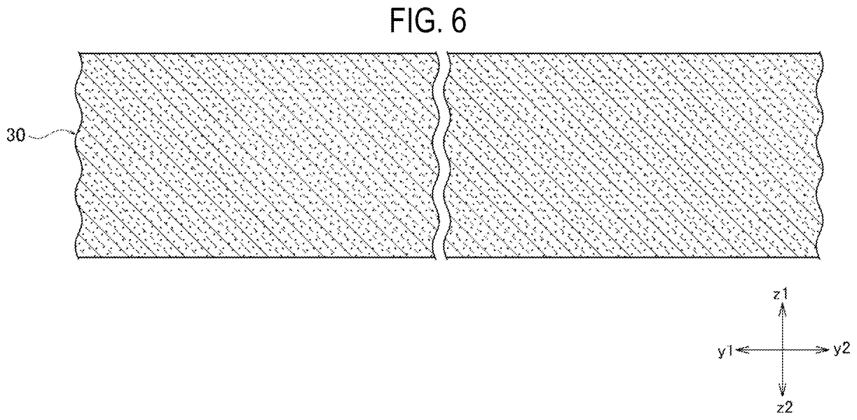

First, as shown in FIG. 6, a substrate 30 provided with a semiconductor layer is prepared. Examples of the semiconductor layer include a silicon layer. The thickness of the substrate 30 is, for example, about 700 to 800 μm.

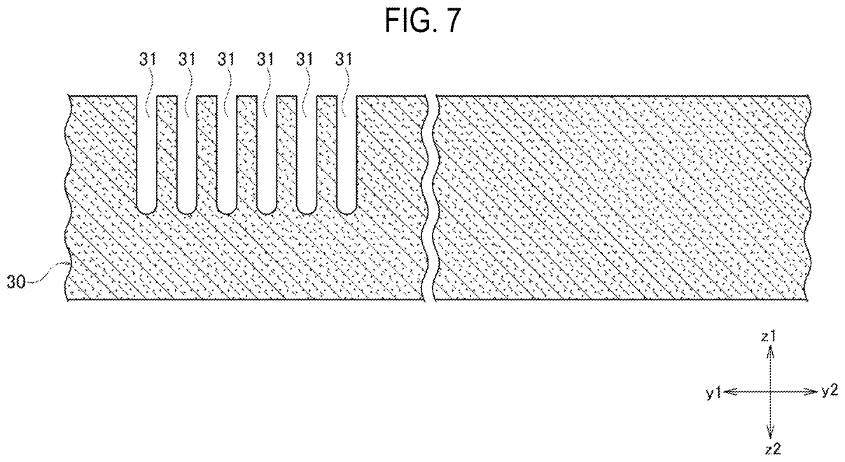

Next, as shown in FIG. 7, a plurality of grooves 31 is formed on the substrate 30. The grooves 31 can be formed by, for example, deep etching such as the Bosch method or the like. As an example of the dimensions of the grooves 31, the diameter of the grooves 31 having a circular shape in the z direction is 0.2 to 0.8 μm, and the pitch (inter-center distance) of the adjacent grooves 31 is 0.4 to 1.4 μm. Further, in the present embodiment, the dimensions of the grooves 31 in the z direction are substantially the same.

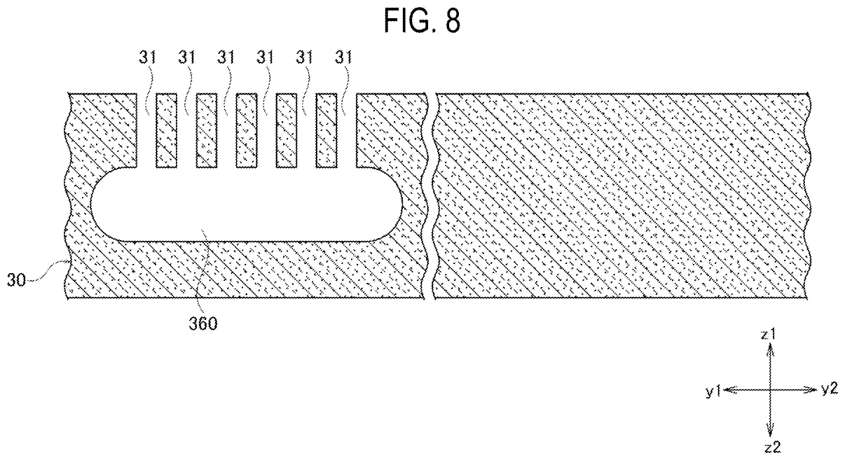

Next, as shown in FIG. 8, the substrate 30 is etched from the bottom surfaces of the grooves 31 in a direction perpendicular to the depth direction of the grooves 31 to form a hollow portion 360 connecting the grooves 31 (hollow portion forming step). In the hollow portion forming step, isotropic etching is performed so that the cross-sectional area perpendicular to the z direction gradually increases. As a result, the step of forming the grooves 31 and the hollow portion forming step can be continuously performed by the same processing, which makes it possible to efficiently form the hollow portion 360.

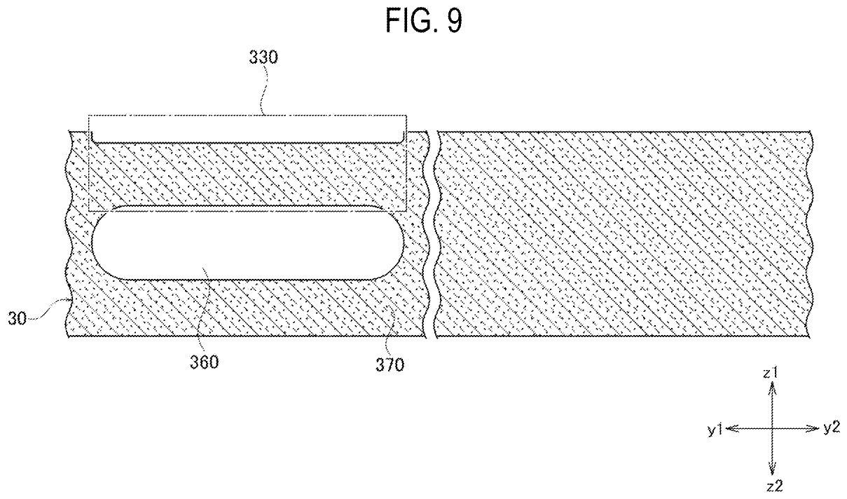

Next, as shown in FIG. 9, the substrate 30 is heat-treated (for example, 1,100 to 1,200 degrees C.) in an atmosphere containing hydrogen. A part of the substrate 30 melted by the heat treatment fills the grooves 31. As a result, the hollow portion 360 is sealed. At the same time, the region 330 of the substrate 30 becomes a part of the movable portion 340 (movable portion forming step). In this manufacturing method, a step of bonding a plurality of different members is not required in order to form the movable portion 340 and the hollow portion 360. This provides an advantage that the airtightness does not deteriorate at the bonded portion. Further, there is an advantage that it is not necessary to provide, for example, excessively large grooves portion penetrating the substrate 30 in order to form the hollow portion 360.

In the movable portion forming step, the grooves 31 are filled by partially moving the semiconductor layer by using thermal migration. Therefore, the movable portion 340 is a portion made of only the material of the semiconductor layer, and is integrally connected to the fixed portion 370 similarly made of the material of the semiconductor layer without a bonding portion. This makes it possible to enhance the airtightness of the hollow portion 360.

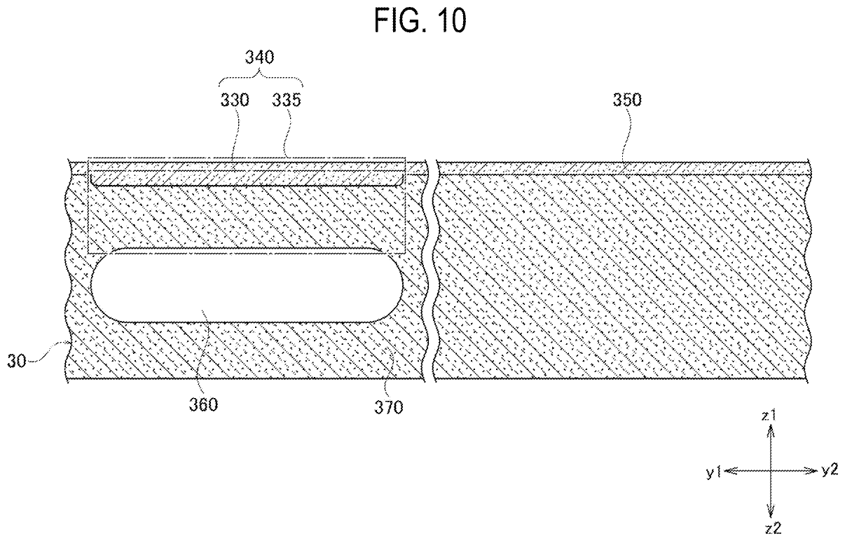

Further, the movable portion 340 has a recess in the region 330. As shown in FIG. 10, an interlayer film 350 is formed on the main surface (recess) of the substrate 30 facing the z1 direction in order to increase the film thickness T of the movable portion 340. The interlayer film 350 has a region 335 that functions as a part of the movable portion 340. Therefore, the movable portion 340 has the region 330 of the substrate 30 and the region 335 of the interlayer film 350. As the interlayer film 350, for example, a silicon layer deposited by a CVD method may be used. Due to the interlayer film 350, the surface on which the protective film 10 is formed becomes a flat surface, and the coverage of the protective film 10 is improved.

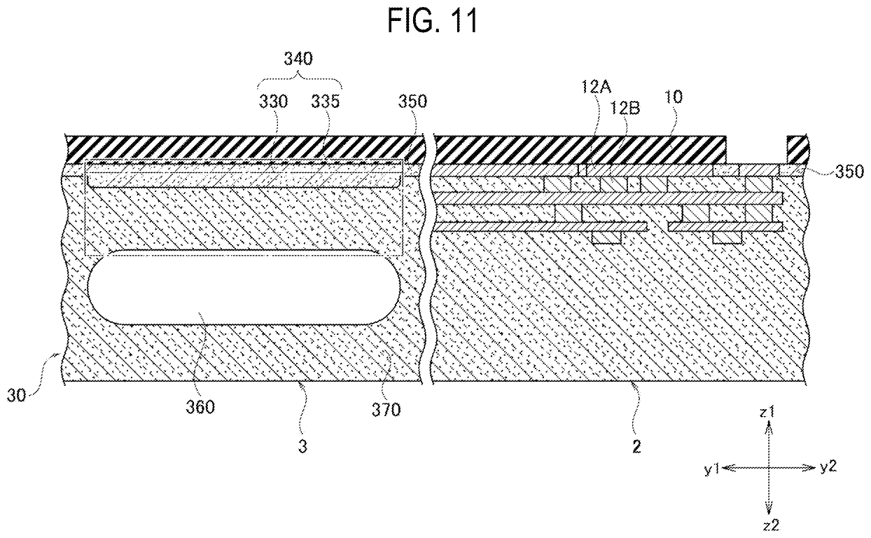

Next, as shown in FIG. 11, a plurality of wirings 12A and a plurality of electrode layers 12B are formed inside the substrate 30 and the interlayer film 350 in the region spaced apart from the region where the MEMS element 3 is formed in a direction (y direction) perpendicular to the thickness direction of the movable portion 340. Further, a protective film 10 that covers the interlayer film 350 and the uppermost (z1 direction side) wirings 12A is formed.

By the above steps, the electronic component 2 and the MEMS element 3 can be manufactured. Since the electronic component 2 and the MEMS element 3 are formed on one chip (substrate 30), the influence of the stress due to the resin 8 formed later on the movable portion 340 can be suppressed, and the process can be simplified. Further, since the electronic component 2 and the MEMS element 3 are not stacked one above the other, the height occupied by the electronic component 2 and the MEMS element 3 can be reduced, and the stress relaxation material 9 can be made thicker. This makes it possible to suppress the influence of external stress on the movable portion 340.

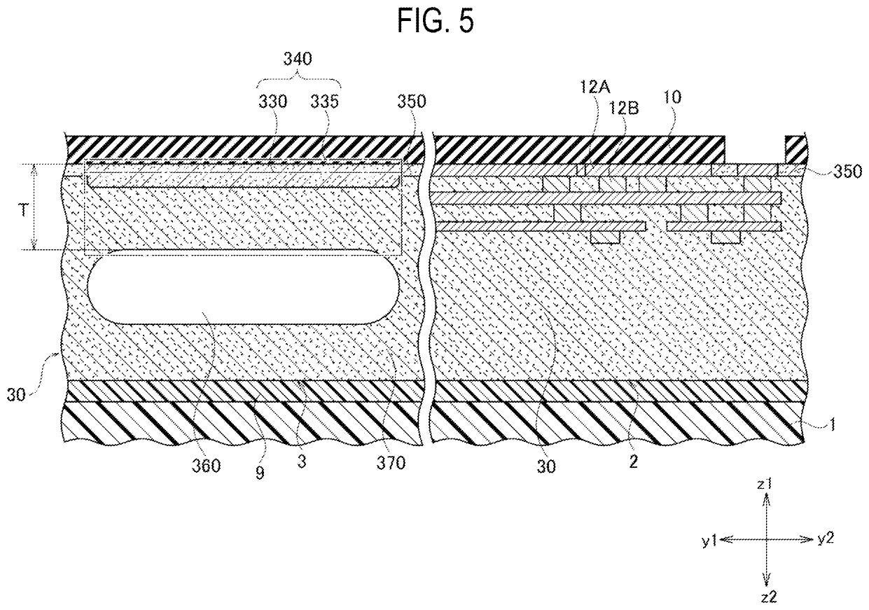

Next, as shown in FIG. 5, the substrate 1, the electronic component 2, and the MEMS element 3 are bonded by the stress relaxation material 9. Further, wirings 4 for electrically connecting the electrode pads 11 of the substrate 1 and the electrode pads 24 of the electronic component 2 are formed and covered with a resin 8. Finally, the cover 6 and the substrate 1 are bonded by the bonding material 7.

By the above steps, the MEMS module A1 can be manufactured. Since the electronic component 2 and the MEMS element 3 are formed on one chip (substrate 30), the stress relaxation material 9 can be made sufficiently thick to suppress the influence of external stress on the movable portion 340.

According to the present embodiment, the MEMS module A1 in which the electronic component 2 and the MEMS element 3 are provided on one chip (substrate 30) can accurately derive a change in external air pressure.

### Second Embodiment

A MEMS module A2 according to a second embodiment will be described.

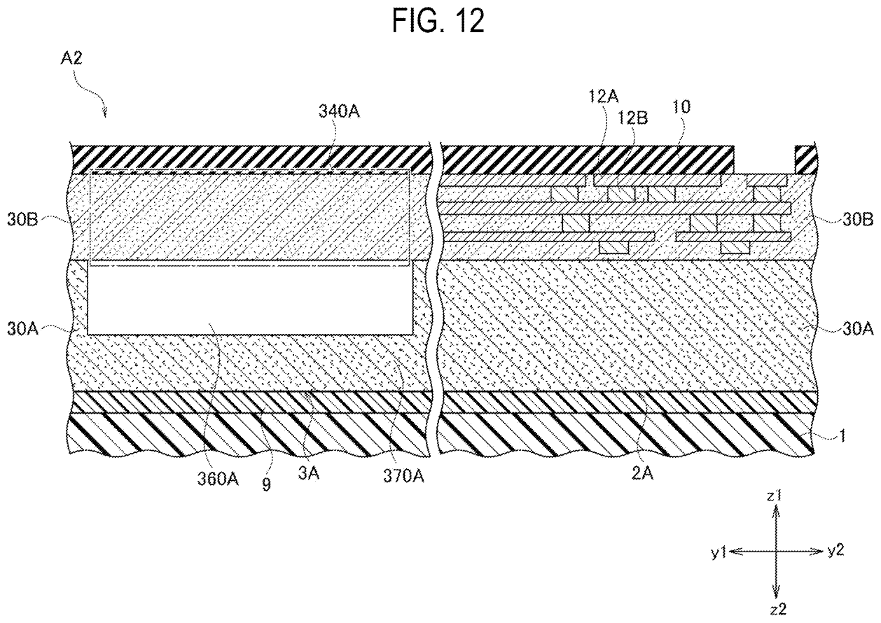

FIG. 12 is a cross-sectional view showing a MEMS element 3A and an electronic component 2A in the MEMS module A2. The MEMS module A2 according to the present embodiment differs from the MEMS module A1 according to the first embodiment in that the interlayer film 350 is not provided, and in terms of the shape and forming method of the hollow portion 360A. The elements of the present embodiment common to the first embodiment (e.g., the substrate 1, the plurality of wirings 4, the cover 6, the bonding material 7, etc.) refer to the description of the first embodiment, and different elements will be described below.

The MEMS element 3A and the electronic component 2A are formed on the substrate 30A and the substrate 30B. The hollow portion 360A of the MEMS element 3A can be formed by bonding a substrate 30A having a groove and a substrate 30B. A plurality of wirings 12A and a plurality of electrode layers 12B of the electronic component 2A are formed inside the substrate 30B.

As the substrate 30A, the same material as the substrate 30 of the first embodiment may be used. Examples of the substrate 30B include an SOI substrate on which an oxide film such as a silicon oxide layer or the like and a semiconductor layer such as a silicon layer or the like are stacked. The thickness of the substrate 30B is, for example, about 700 to 800 μm.

The hollow portion 360A is hermetically sealed. The hollow portion 360A may be kept in vacuum. Further, in the present embodiment, the hollow portion 360A has a rectangular shape in a z-direction view. However, the present disclosure is not limited thereto. The depth (dimension in the z direction) of the hollow portion 360A is, for example, 5 to 15 μm.

The description of the movable portion 340 and the fixed portion 370 of the first embodiment may be referred for the movable portion 340A and the fixed portion 370A. Since the groove of the substrate 30A becomes the hollow portion 360A and the main surface (main surface on the z1 direction side) of the movable portion 340A is formed from the substrate 30B, the movable portion 340A is not thin unlike the movable portion 340 of the first embodiment, and has a thickness large enough to function as a movable portion. Therefore, unlike the first embodiment, it is not necessary to provide the interlayer film 350.

Next, a method of manufacturing the MEMS module A2 will be described.

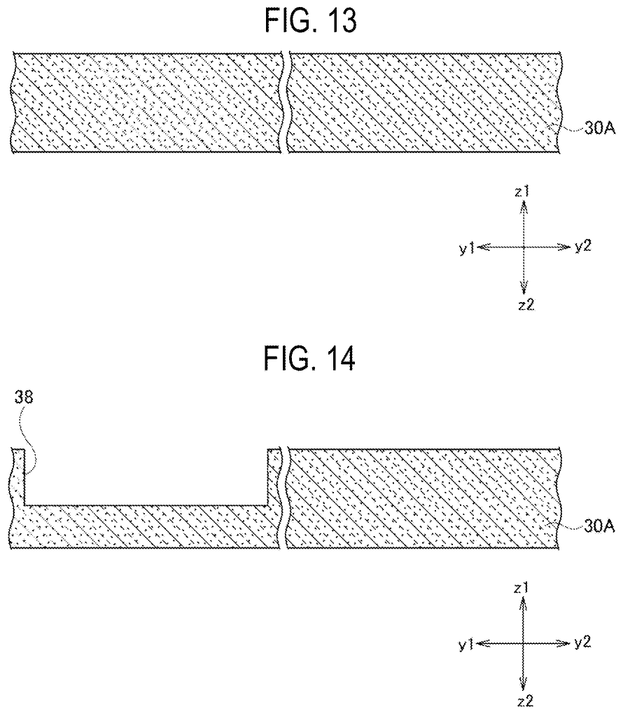

First, as shown in FIG. 13, a substrate 30A provided with a semiconductor layer is prepared. Examples of the semiconductor layer include a silicon layer. The thickness of the substrate 30A is, for example, about 700 to 800 μm.

Next, as shown in FIG. 14, a groove 38 is formed on the substrate 30A. The groove 38 may be formed by etching, for example.

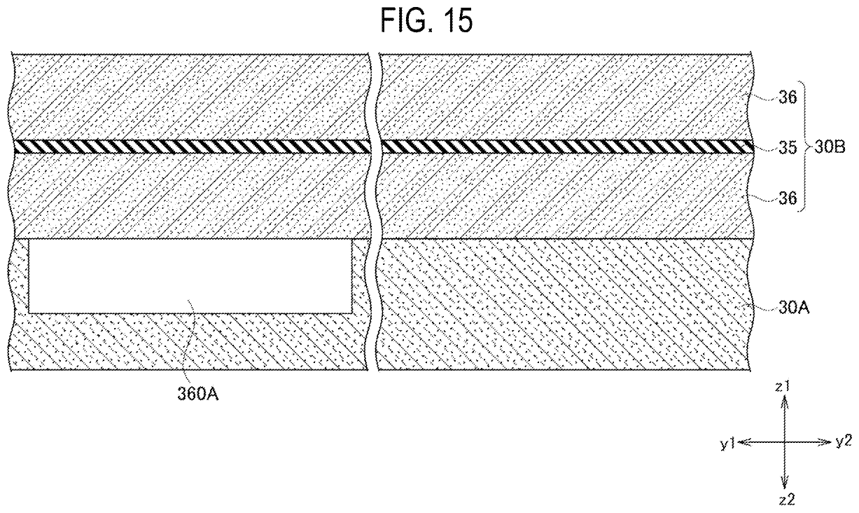

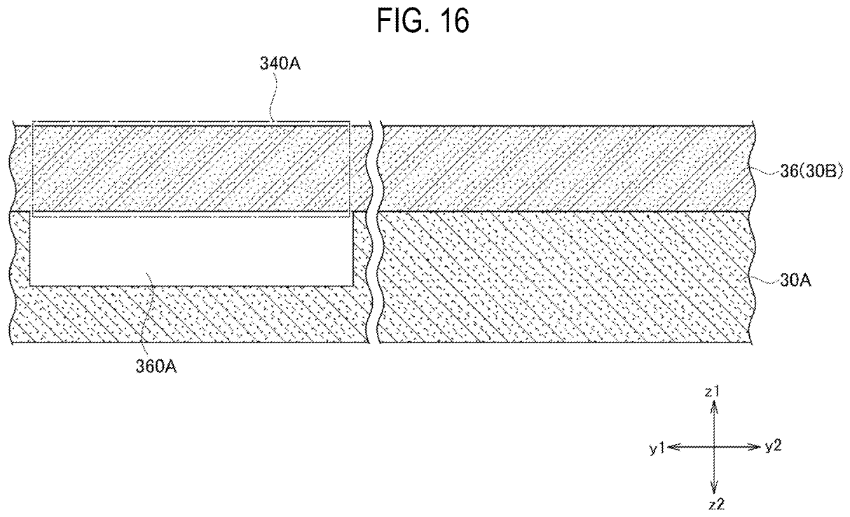

Next, as shown in FIG. 15, the substrate 30B is bonded to the substrate 30A to form a hollow portion 360A. Further, in the present embodiment in which the movable portion 340A is formed at the same time, the substrate 30B is an SOI substrate on which an oxide film 35 and a semiconductor layer 36 are stacked. When a part of the substrate 30B is removed in a later step, the depth of the hollow portion 360A can be fixed and good reproducibility can be obtained because the oxide film 35 has a large etching selectivity with respect to the semiconductor layer 36 and only the oxide film 35 is etched.

Next, as shown in FIG. 16, a part of the substrate 30B (the oxide film 35 and the semiconductor layer 36) is removed. The removal can be performed, for example, by etching with hydrogen fluoride or the like. The main surface (main surface on the z1 direction side) of the remaining semiconductor layer 36 may be subjected to a flattening process so as to obtain a flatter surface. The flattening process may include, for example, grinding, and providing an interlayer film having a flat surface.

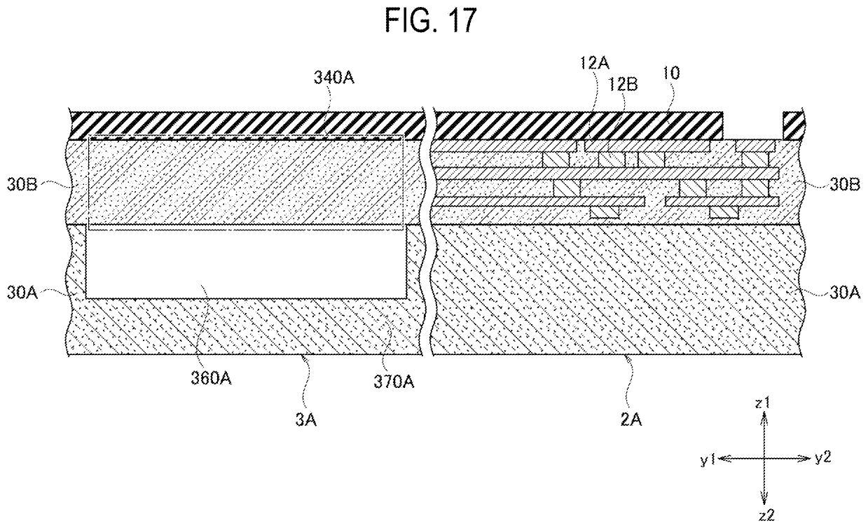

Next, as shown in FIG. 17, a plurality of wirings 12A and a plurality of electrode layers 12B are formed inside the substrate 30B in the region spaced apart from the region where the MEMS element 3A is formed in a direction (y direction) perpendicular to the thickness direction of the movable portion 340A. Further, a protective film 10 that covers the substrate 30B and the uppermost (z1 direction side) wirings 12A is formed.

By the above steps, the electronic component 2A and the MEMS element 3A can be manufactured. Since the electronic component 2A and the MEMS element 3A are formed on one chip (substrate 30A and substrate 30B), the influence of the stress due to the resin 8 formed later on the movable portion 340A can be suppressed, and the process can be simplified. Further, since the electronic component 2A and the MEMS element 3A are not stacked one above the other, the height occupied by the electronic component 2A and the MEMS element 3A can be reduced, and the stress relaxation material 9 can be made thicker. This makes it possible to suppress the influence of external stress on the movable portion 340A.

Next, as shown in FIG. 12, the substrate 1, the electronic component 2A, and the MEMS element 3A are bonded by a stress relaxation material 9. Further, wirings 4 for electrically connecting the electrode pads 11 of the substrate 1 and the electrode pads 24 of the electronic component 2 are formed and covered with a resin 8. Finally, the cover 6 and the substrate 1 are bonded by the bonding material 7.

By the above steps, the MEMS module A2 can be manufactured. Since the electronic component 2A and the MEMS element 3A are formed on one chip (substrate 30A and substrate 30B), the stress relaxation material 9 can be made sufficiently thick to suppress the influence of external stress on the movable portion 340A.

According to the present embodiment, the MEMS module A2 in which the electronic component 2A and the MEMS element 3A are provided on one chip (substrate 30A and substrate 30B) can accurately derive a change in external air pressure.

### Third Embodiment

A MEMS module A3 according to a third embodiment will be described.

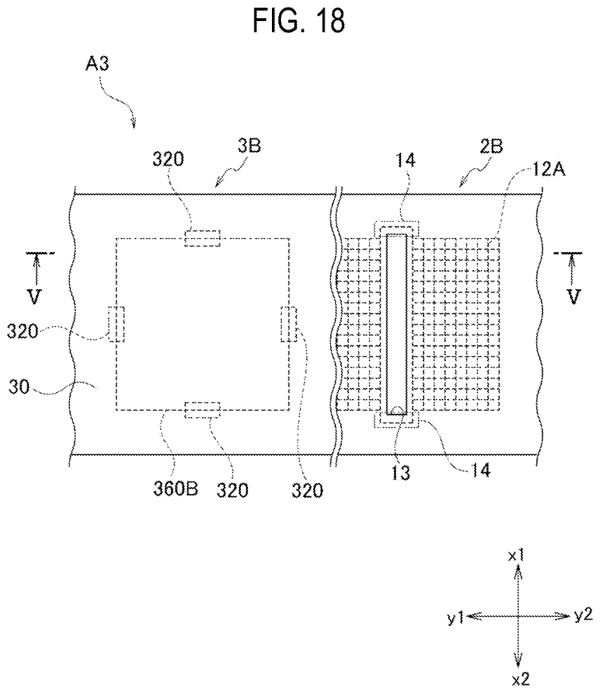

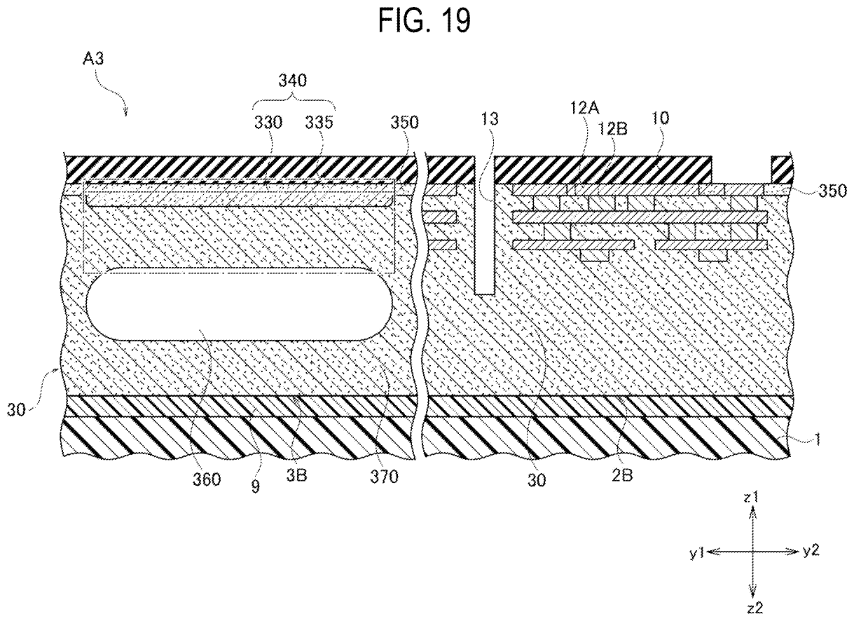

FIG. 18 is a plan view showing a MEMS element 3B and an electronic component 2B in the MEMS module A3. FIG. 19 is a cross-sectional view taken along line V-V in FIG. 18. The difference between the MEMS module A3 according to the present embodiment and the MEMS module A1 according to the first embodiment is that the substrate 30 includes a groove 13 extending in the thickness direction from the main surface of the substrate 30 facing the z1 direction between the MEMS element 3B and the electronic component 2B. The elements of the present embodiment common to the first embodiment (e.g., the substrate 1, the plurality of wirings 4, the cover 6, the bonding material 7, etc.) refer to the description of the first embodiment, and different elements will be described below.

Further, the MEMS element 3B and the electronic component 2B are electrically connected to the wirings 12A. The wirings 12A have a region 14 located on the outer edge side of the substrate 30 from the end portion of the groove 13 in the x direction.

By providing the groove 13, the stress applied to the MEMS element 3B and the stress applied to the electronic component 2B can be separated from each other, and the influence of the stress applied to the electronic component 2B on the MEMS element 3B can be suppressed.

Further, the MEMS element 3B may refer to the description of the MEMS element 3 of the first embodiment.

In a method of manufacturing the MEMS module A3, for example, when the plurality of wirings 12A and the plurality of electrode layers 12B according to the first embodiment are formed, the wirings 12A are formed so as to have a region 14 located on the outer edge side of the substrate 30 from the end portion of the groove 13 in the x direction. Thereafter, the protective film 10 is formed as in the first embodiment, the substrate 1, the electronic component 2B, and the MEMS element 3B are bonded by the stress relaxation material 9, the wirings 4 are formed, the wirings 4 are covered with the resin 8, and the cover 6 and the substrate 1 are bonded by the bonding material 7, whereby the MEMS module A3 can be manufactured.

According to the present embodiment, the MEMS module A3 in which the electronic component 2B and the MEMS element 3B are provided on one chip (substrate 30) can accurately derive a change in external air pressure.

### Fourth Embodiment

A MEMS module A4 according to a fourth embodiment will be described.

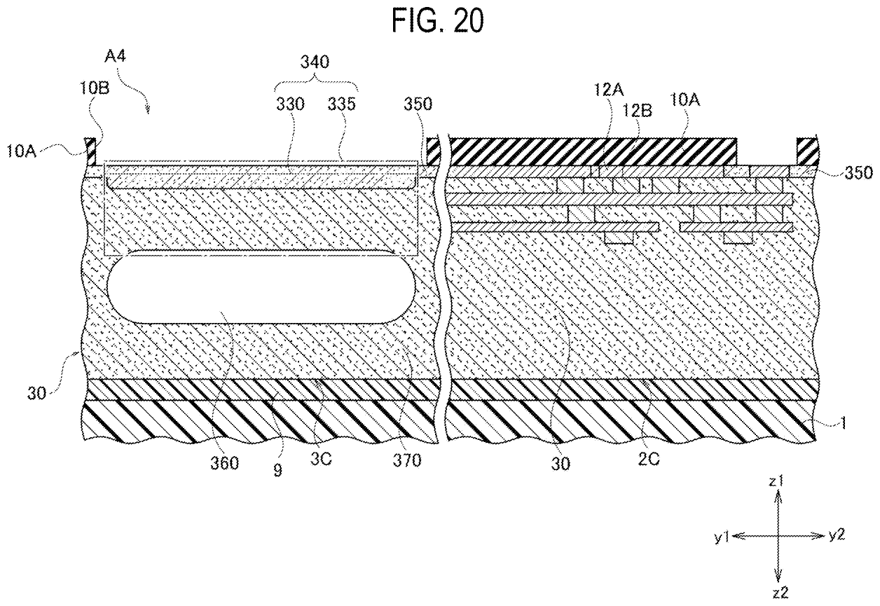

FIG. 20 is a cross-sectional view showing a MEMS element 3C and an electronic component 2C in the MEMS module A4. The difference between the MEMS module A4 according to the present embodiment and the MEMS module A1 according to the first embodiment is that a protective film 10A including an opening 10B is provided. The elements of the present embodiment common to the first embodiment (e.g., the substrate 1, the plurality of wirings 4, the cover 6, the bonding material 7, etc.) refer to the description of the first embodiment, and different elements will be described below.

The MEMS element 3C includes a protective film 10A including an opening 10B. The opening 10B is located above the movable portion 340 when viewed in the thickness direction (x direction) of the movable portion 340. By providing the opening 10B of the protective film 10A, it is possible to suppress the stress caused by the protective film 10A or the like and applied to the MEMS element 3C.

Further, the electronic component 2C may refer to the description of the electronic component 2 of the first embodiment.

In a method of manufacturing the MEMS module A4, for example, after forming the protective film 10 according to the first embodiment, the opening 10B is formed above the movable portion 340 when viewed in the thickness direction (x direction) of the movable portion 340 by etching or the like, whereby the protective film 10A including the opening 10B can be obtained. Thereafter, as in the first embodiment, the substrate 1, the electronic component 2C, and the MEMS element 3C are bonded by the stress relaxation material 9, the wirings 4 are formed, the wirings 4 are covered with the resin 8, and the cover 6 and the substrate 1 are bonded by the bonding material 7, whereby the MEMS module A4 can be manufactured.

### Other Embodiments

While the embodiments of the present disclosure have been described above, the descriptions and drawings that form a part of the disclosure are exemplary and should not be understood as being limitative. The present disclosure will reveal various alternative embodiments, examples, and operational techniques to those skilled in the art. In this way, the present disclosure includes various embodiments not described herein.

According to the present disclosure in some embodiments, it is possible to provide a MEMS module capable of accurately deriving a change in outside air pressure. Further, it is possible to provide a method of manufacturing a MEMS module.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A MEMS module comprising:
a MEMS element provided with a substrate in which a hollow portion is formed, and including a movable portion, which is a part of the substrate, around the hollow portion, the movable portion having a thickness whose shape is changeable by an air pressure difference between an air pressure inside the hollow portion and an air pressure outside the substrate; and
an electronic component, to which an output signal of the MEMS element is inputted, formed on the substrate,
wherein the electronic component and the MEMS element are spaced apart from each other in a direction perpendicular to a thickness direction of the movable portion.

2. The MEMS module of claim 1, wherein the substrate includes a groove, which extends from a main surface of the substrate in a thickness direction of the substrate, between the MEMS element and the electronic component.

3. The MEMS module of claim 2, further comprising:
a first wiring having a region located on an outer edge side of the substrate from an end of the groove, in a direction in which the electronic component and the MEMS element are spaced apart from each other and a direction which is perpendicular to the thickness direction of the movable portion,
wherein the MEMS element and the electronic component are electrically connected to the first wiring.

4. The MEMS module of claim 1, further comprising:
a protective film including an opening on the substrate,
wherein the protective film covers at least a part of the electronic component, and
wherein the opening is located above the movable portion when viewed in the thickness direction of the movable portion.

5. The MEMS module of claim 1, further comprising:
a printed circuit board; and
a stress relaxation material arranged between the printed circuit board and the MEMS element,
wherein a thickness of the stress relaxation material is 35 to 80 μm.

6. The MEMS module of claim 5, further comprising:
a second wiring configured to electrically connect the printed circuit board and the electronic component,
wherein the second wiring is electrically connected to the electronic component, on a side of the electronic component that is opposite to a side on which the MEMS element is located.

7. The MEMS module of claim 1, wherein the substrate is made of silicon.

8. A method of manufacturing a MEMS module, comprising:
forming a plurality of grooves in a semiconductor layer included in a substrate;
forming a MEMS element including a hollow portion formed by:
etching the semiconductor layer in a direction perpendicular to a depth direction of the grooves from bottom surfaces of the grooves to connect the grooves;
performing a heat treatment on the semiconductor layer; and
filling the grooves with a part of the semiconductor layer melted by the heat treatment; and
forming an electronic component, to which an output signal of the MEMS element is inputted, on the substrate,
wherein the electronic component and the MEMS element are spaced apart from each other in the direction perpendicular to the depth direction of the grooves.

9. The method of claim 8, wherein the hollow portion is formed by deep etching and isotropic etching.

10. The method of claim 8, wherein the heat treatment is performed at 1,100 to 1,200 degrees C. to cause a thermal migration phenomenon in the semiconductor layer to fill the grooves and form the hollow portion.

11. A method of manufacturing a MEMS module, comprising:
preparing a first substrate provided with a semiconductor layer and a second substrate in which a semiconductor layer is stacked on an oxide film;
forming an opening in the first substrate;
forming a MEMS element including a hollow portion formed in the opening of the first substrate by bonding the second substrate on the first substrate in which the opening is formed; and
forming an electronic component, to which an output signal of the MEMS element is inputted, on the first substrate,
wherein the electronic component and the MEMS element are spaced apart from each other in a direction perpendicular to a depth direction of the opening.

12. The method of claim 11, wherein the oxide film is a silicon oxide layer.

13. The method of claim 8, wherein the semiconductor layer is a silicon layer.
